(19) United States
(12) Patent Application Publication
(10) Pub. No.: US 2021/0328165 A1
(43) Pub. Date: Oct. 21, 2021

(54) EMISSIVE LAYER WITH LAYERED QUANTUM DOTS WITH DIFFERENT LIGANDS FOR QLEDS

(71) Applicant: SHARP KABUSHIKI KAISHA, Sakai City (JP)

(72) Inventors: ANDREA ZAMPETTI, Abingdon (GB); ENRICO ANGIONI, Oxford (GB); EDWARD ANDREW BOARDMAN, Abingdon (GB); TIM MICHAEL SMEETON, Oxford (GB)

(21) Appl. No.: 16/854,877

(22) Filed: Apr. 21, 2020

(51) Int. Cl. H01L 51/50

(52) U.S. Cl. CPC H01L 51/502; H01L 51/5072; H01L 51/5056

(57) ABSTRACT

A light emitting device comprises a first electrode, a second electrode, and an emissive layer between the first and the second electrodes. The emissive layer comprises a first plurality of quantum dots having hole transporting ligands, and a second plurality of quantum dots having electron transporting ligands, where at least one of the first and the second plurality of quantum dots is incorporated in a matrix. The matrix comprises at least one of an electrically insulating material, a photo-responsive material, and a dielectric material. The matrix comprises cross-linked molecules, the cross-linked molecules transport charge carriers to or away from the at least one of the first plurality of quantum dots and the second plurality of quantum dots that is incorporated in the matrix.

### FIELD

The present disclosure relates to an emissive layer (EML) having quantum dots (QDs) of high quantum efficiency and high carrier mobility, applications of the EML in light-emitting devices (LEDs) and methods of manufacturing the LEDs. Specifically, the EML includes multiple layers each including QDs with different ligands and a matrix material.

A first layer of the EML is made of QDs with hole transport ligands and a second layer of the EML made of QDs with electron transport ligands, in a matrix material, and at least one of the first and the second layers is incorporated in the matrix material. The LEDs may be implemented in display applications, such as high resolution multi-colour displays.

### BACKGROUND

QDs are nano-crystalline semiconductor materials made of cores, shells and ligands. One feature of QDs is that the quantum confinement effect via which the wavelength of light emitted from the QDs depends on a size of a quantum dot.

QDs can provide emitted light with better color purity and generate light with higher internal quantum efficiency (IQE) compared to organic semiconductors. These properties have attracted a wide attention in optoelectronic devices, such as LEDs. However, the QDs do not reach maximum theoretical efficiency when used as an EML in a QD-LED.

A conventional QD-LED includes a QD light-emitting layer between a hole transport layer (HTL) and an electron transport layer (ETL). Charge injection from the ETL to the EML is generally efficient in most QD-LEDs due to a good match between the conduction band (CB) of the ETL (from 3.00 eV to 4.5 eV) and the CB of the QD layers (from 2.8 eV to 3.8 eV).

However, QD-LEDs generally suffer from relatively poor hole injection from the HTL to the QD layer. This is usually a consequence of both the significant energy barrier height at the interface between HTL and QDs, the valence band (VB) of which can reach up to 7 eV, and the use of organic ligands that are generally insulating. Combinations of these factors result in a charge accumulation at HTL/QD interface and an inefficient charge balance in the EML. These factors contribute to both an increase of the operating voltages and a decrease of the efficiency of the LEDs.

Therefore, there is a need for QDs with better energy level alignment with hole transport materials or synthetized optimized hole transport materials for the EML. One of the most promising strategies is surface modification of QDs via QD core/shell or ligand engineering.

U.S. Pat. No. 8,120,010 B2 (Kyung Sang CHO, et al., published May 6, 2010) describes a QD light-emitting multi-layer with different ligand distribution. The QD EML has a first surface in contact with an HTL and a second surface in contact with an ETL where the first surface has an organic ligand distribution that is different from an organic ligand distribution of the second surface in order to alter the electronegativity of the ligand at the interface with the related charge transporting layer. The surface modification reported is, therefore, a partial ligand exchange of QDs.

U.S. Pat. No. 10,436,155 (Jae-Hyun Park, et al., published Mar. 14, 2019) describes a light-emitting layer incorporating QDs with two types of ligand on the outer surface. The QDs feature both an X-type ligand that includes a functional group selected from a carboxylate group, a phosphate group, and a thiolate group bound to a first region of the outer surface and an L-type ligand that includes a functional group selected from an amino group, a thiol group, a phosphine group, and a phosphine oxide group bound to a second region of the outer surface.

Korean Patent Publication No. KR1020130047943A (LG Display Co. Ltd., published May 9, 2013) describes a multi-layer QD EML including a first QD with hole transport ligands and a second QD with electron transport ligands deposited by solution processing. The suggested ligands are the triarylamine-based material (hole transport ligand) and heterocyclic compounds (electron transport ligands).

U.S. Pat. No. 8,330,142 B2 (Kyung-sang CHO, et al., published Aug. 26, 2010) describes a double QD emitting layer exhibiting a band offset to match either HTL or ETL energy levels at the related interfaces.

‘Bright and efficient quantum dot light-emitting diodes with double light-emitting layers’ by Zhang et al., DOI: 10.1364/OL.43.005925, published Dec. 4, 2018, describes high brightness and efficient light-emitting diodes with double QD light-emitting layers evenly spaced by a poly(p-phenylene benzobisoxazole)-based interlayer. The interlayer acts as an electron blocking layer to uniformly distribute the charge balance within the EML.

‘Efficient light-emitting diodes based on nanocrystalline perovskite in a dielectric polymer matrix’ by Guangru Li et al., DOI: 10.1021/acs.nanolett.5b00235, published Feb. 24, 2015, describes light emitting diodes with a perovskite EML incorporating a polyimide-based dielectric matrix. The method blocks electrical shunt within the EML and enhances the efficiency of the device.

### CITATION LIST

U.S. Pat. No. 8,120,010 B2 to Kyung Sang CHO, et al., published May 6, 2010.
U.S. Pat. No. 10,436,155 to Jae-Hyun Park, et al., published Mar. 14, 2019.
Korean Patent Publication No. KR1020130047943A to LG Display Co. Ltd., published May 9, 2013.
U.S. Pat. No. 8,330,142 B2 to Kyung-sang CHO, et al., published Aug. 26, 2010.
‘Bright and efficient quantum dot light-emitting diodes with double light-emitting layers’ by Zhang et al., DOI: 10.1364/OL.43.005925, published Dec. 4, 2018.
‘Efficient light-emitting diodes based on nanocrystalline perovskite in a dielectric polyer matrix’ by Guangru Li et al., DOI: 10.1021/acs.nanolett.5b00235, published Feb. 24, 2015.

### SUMMARY

According to a first aspect of the present disclosure, a light emitting device includes a first electrode; a second electrode; and an emissive layer between the first and the second electrodes, the emissive layer comprising: a first plurality of quantum dots having hole transporting ligands; and a second plurality of quantum dots having electron transporting ligands, where at least one of the first plurality of quantum dots and the second plurality of quantum dots is incorporated in a matrix.

According to an implementation of the first aspect, the first plurality of quantum dots is disposed in a first layer of the emissive layer, and the second plurality of quantum dots is disposed in a second layer of the emissive layer.

According to another implementation of the first aspect, the matrix comprises at least one of an electrically insulating material, a photo-responsive material, and a dielectric material.

According to yet another implementation of the first aspect, the matrix comprises cross-linked molecules, the cross-linked molecules transport charge carriers to or away from the at least one of the first plurality of quantum dots and the second plurality of quantum dots that is incorporated in the matrix.

According to yet another implementation of the first aspect, the matrix isolates and confines the at least one of the first plurality of quantum dots and the second plurality of quantum dots at an interface between the matrix and the at least one of the first plurality of quantum dots and the second plurality of quantum dots that is incorporated in the matrix.

According to yet another implementation of the first aspect, the light emitting device also includes a hole transporting layer between the emissive layer and the first electrode, the first electrode being an anode electrode.

According to yet another implementation of the first aspect, the light emitting device also includes a hole injecting layer between the hole transporting layer and the anode electrode.

According to yet another implementation of the first aspect, the light emitting device also includes an electron transporting layer between the emissive layer and the second electrode, the second electrode being a cathode electrode.

According to yet another implementation of the first aspect, the light emitting device also includes an electron injecting layer between the electron transporting layer and the cathode electrode.

According to yet another implementation of the first aspect, at least one quantum dot in the first and the second pluralities of quantum dots comprises a core and at least one shell enclosing the core.

According to yet another implementation of the first aspect, the light emitting device also includes a substrate, where the first electrode is an anode disposed on one side of the emissive layer facing the substrate, and where the second electrode is a cathode disposed on another side of the emissive layer facing away from the substrate.

According to yet another implementation of the first aspect, the light emitting device also includes a hole transporting layer between the first electrode and the emissive layer; and an electron transporting layer between the emissive layer and the second electrode.

According to yet another implementation of the first aspect, the light emitting device also includes a substrate, where the first electrode is a cathode disposed on one side of the emissive layer facing the substrate; and where the second electrode is an anode disposed on another side of the emissive layer facing away from the substrate.

According to yet another implementation of the first aspect, the light emitting device also includes an electron transporting layer between the first electrode and the emissive layer; and a hole transporting layer between the emissive layer and the second electrode.

According to a second aspect of the present disclosure, an emissive layer of a light emitting device is disclosed. The emissive layer includes: a first plurality of quantum dots having hole transporting ligands; and a second plurality of quantum dots having electron transporting ligands, where at least one of the first plurality of quantum dots and the second plurality of quantum dots is incorporated in a matrix.

According to an implementation of the second aspect, the matrix comprises at least one of an electrically insulating material, a photo-responsive material, and a dielectric material.

According to another implementation of the second aspect, the matrix comprises cross-linked molecules, the cross-linked molecules transport charge carriers to or away from the at least one of the first plurality of quantum dots and the second plurality of quantum dots that is incorporated in the matrix.

According to yet another implementation of the second aspect, the matrix isolates and confines the at least one of the first plurality of quantum dots and the second plurality of quantum dots at an interface between the matrix and the at least one of the first plurality of quantum dots and the second plurality of quantum dots that is incorporated in the matrix.

According to yet another implementation of the second aspect, at least one quantum dot in the first and the second pluralities of quantum dots comprises a core and at least one shell enclosing the core.

### BRIEF DESCRIPTION OF DRAWINGS

Aspects of the disclosure are best understood from the following detailed description when read with the accompanying figures. Various features are not drawn to scale. Dimensions of various features may be arbitrarily increased or reduced for clarity of discussion.

FIG. 1 illustrates a schematic cross-sectional view of an LED in accordance with an example implementation of the present disclosure.

FIG. 2A illustrates a schematic diagram of a single shelled QD in accordance with an example implementation of the present disclosure.

FIG. 2B illustrates a schematic diagram of a multiple shelled QD in accordance with an example implementation of the present disclosure.

FIG. 3A illustrates a schematic diagram of an EML in accordance with an example implementation of the present disclosure.

FIG. 3B illustrates a schematic diagram of QDs in the EML of FIG. 3A in accordance with an example implementation of the present disclosure.

FIG. 4A illustrates a schematic diagram of an EML in accordance with another example implementation of the present disclosure.

FIG. 4B illustrates a schematic diagram of QDs in the EML of FIG. 4A in accordance with an example implementation of the present disclosure.

### DETAILED DESCRIPTION

The following description contains specific information related to the present disclosure. The drawings and their accompanying detailed description are directed to example implementations. However, the present disclosure is not limited to these example implementations. Other variations and implementations of the present disclosure will occur to those skilled in the art.

Unless noted otherwise, like or corresponding elements in the figures may be indicated by like or corresponding reference numerals. The drawings and illustrations are generally not to scale and are not intended to correspond to actual relative dimensions.

For the purpose of consistency and ease of understanding, like features may be identified (although, in some examples, not shown) by the same numerals in the figures. However, the features in different implementations may be different in other respects and shall not be narrowly confined to the figures.

The phrases “in one implementation,” or “in some implementations” may each refer to one or more of the same or different implementations. The term “coupled” is defined as “connected, whether directly or indirectly through intervening components” and is not necessarily limited to physical connections. The term “comprising” means “including, but not necessarily limited to” and specifically indicates an open-ended inclusion or membership in the disclosed combination, group, series or equivalent. The expression “at least one of A, B and C” or “at least one of the following: A, B and C” means “only A, or only B, or only C, or any combination of A, B and C.”

For purposes of explanation and non-limitation, specific details such as functional entities, techniques, protocols, and standards are set forth to provide an understanding of the disclosed technology. Detailed description of well-known methods, technologies, systems, and architectures are omitted so as not to obscure the disclosure with unnecessary details.

The present disclosure is related to an enhanced QD-LED layer structure and methods of fabricating such a structure that achieve both efficient charge injection from charge transport materials to a light-emitting layer and charge balance within the EML. The EML of the present disclosure incorporates multi-layered QDs with either electron transporting ligands or hole transporting ligands in a matrix for peak efficiency for emitting light. The matrix may include photo-responsive materials, dielectric materials, or insulating materials. The EML of the present disclosure prevents exciton quenching at interfaces of QDs with both charge transporting ligands and charge transport materials.

Combining QDs with a photo-resist matrix in order to deposit the EMLs via photolithography techniques is highly desirable. The EML according to the present disclosure provides photolithography that improves QD uniformity across the EML by increasing robustness of each QD layer and hinders intermixing of consecutive QD layers during sequential deposition steps that can improve charge transport properties within the QD-LED.

Using a photo-resist matrix may overcome charge transporting issues between the QD layers in QDs having different ligands attached. A fabrication method based on a photo-responsive matrix allows fabrication of high-resolution sub-pixels using a simple process such as UV lithography.

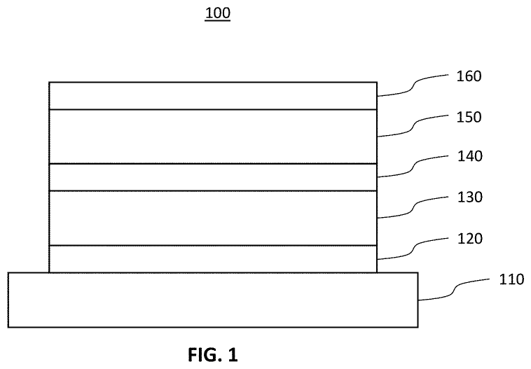

FIG. 1 illustrates a schematic diagram of an LED 100 having a QD-LED structure according to the present disclosure. Several planar layers are deposited sequentially on a substrate 110. The substrate 110 may be made of any suitable material such as rigid substrates typically made of glass or flexible substrates made of polyimide, polyethylene, polythene or polyester materials.

A first electrode 120 is deposited directly on the substrate. The first electrode 120 may be an anode conventionally known as a direct structure or a cathode conventionally known as an inverted structure.

The first electrode 120 is semi-transparent in a bottom-emitting device where light is primarily emitted from a substrate side. Typical materials for the first electrode 120 include indium tin oxide (ITO), fluorine doped tin oxide (FTO) or indium zinc oxide (IZO). The first electrode 120 in a top-emitting device where light is primarily emitted from a terminal electrode side may be made of any suitable reflective metal, such as silver or aluminium.

A second electrode 160 is the final deposited layer in the QD-LED stack. An EML 140 is inserted between the first electrode 120 and the second electrode 160.

The second electrode 160 in bottom-emitting devices is a reflective electrode. Typical materials used for the second electrode 160 include metals, such as calcium, aluminium or silver (cathodes for direct structures) and copper, silver, gold or platinum (anodes for inverted structures). A material of the second electrode 160 in a top-emitting structure is semi-transparent, such as a thin layer (<20 nm) of silver, and ultrathin electrode, such as a bilayer consisting in 1-nm thick aluminium and thin layer of silver.

A first charge transport layer (CTL) 130 deposited on the first electrode 120 in direct structures is a hole transport layer. The first CTL 130 may include one or more layers optimized to transport holes from the first electrode 120 (an anode electrode) into the EML 140.

The first CTL 130 (hole transporting) may include any suitable materials. The first CTL 130 may include organic polymeric materials such as poly(3,4-ethylenedioxythiophene):poly(styrenesulfonate) (PEDOT:PSS), poly(9,9-dioctylfluorene-co-N-(4-sec-butylphenyl)-diphenylamine) (TFB), poly(9-vinylcarbazole) (PVK), poly(N,N′-bis(4-butylphenyl)-N,N′-bisphenylbenzidine) (poly-TPD), metal oxide materials (V₂O₅, NiO, CuO, WO₃, MoO₃) or organic small molecule materials such as 2,3,5,6-tetrafluoro-7,7,8,8-tetracyanoquinodimethane (F4TCNQ), 1,4,5,8,9,11-hexaazatriphenylenehexacarbonitrile (HATCN), N4,N4′-Bis(4-(6-((3-ethyloxetan-3-yl)methoxy)hexyl)phenyl)-N4,N4′-diphenylbiphenyl-4,4′-diamine (OTPD), N4,N4′-Bis(4-(6-((3-ethyloxetan-3-yl)methoxy)hexyloxy)phenyl)-N4,N4′-bis(4-methoxyphenyl)biphenyl-4,4′-diamine (QUPD), and N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC), Copper(I) thiocyanate (CuSCN). If the first CTL 130 includes more than one layer, each layer may be made of a different material.

The penultimate layer shown in FIG. 1 as the second electrode 160 (a terminal electrode) is a second CTL 150 that is electron transporting. The second CTL 150 may include one or more layers and may be made from any suitable materials that are optimized to transport electrons to the EML 140. The second CTL 150 may include metal oxides such as ZnO, MgₓZn₁₋ₓO where 0≤x≤1, AlₓZn₁₋ₓO where 0≤x≤1, GaₓZn₁₋ₓO where 0≤x≤1, amorphous titanium oxide, TiO₂ and ZrO₂, organic small molecules such as 2,2′,2″-(1,3,5-benzinetriyl)-tris(1-phenyl-1-H-benzimidazole) (TPBi), N4,N4′-Di(naphthalen-1-yl)-N4,N4′-bis(4-vinylphenyl)biphenyl-4,4′-diamine (VNPB), and 9,9-Bis [4-[(4-ethenylphenyl)methoxy]phenyl]-N2,N7-di-1-naphthalenyl-N2,N7-diphenyl-9H-Fluorene-2,7-diamine (VB-FNPD) and thin ionic interlayers such as 8-quinolinolato lithium (Liq.), LiF, Cs₂CO₃. In implementations where the second CTL 150 includes more than one layer, each layer may be made of a different material

The LED 100 may include one or more additional layers such as a hole injection layer and/or an electron injection layer. Suitable materials for the hole injection layer include, but are not limited to, poly(3,4-ethylenedioxythiophene) polystyrene sulfonate (PEDOT:PSS), molybdenum oxide (MoO₃), a mixture of MoO3:PEDOT:PSS; V₂O₅, a mixture of PEDOT:PSS:V₂O₅, WO₃, MoO₃, 2,3,5,6-tetrafluoro-7,7,8,8-tetracyanoquinodimethane (F4TCNQ), and/or 1,4,5,8,9,11-hexaazatriphenylenehexacarbonitrile (HATCN). Suitable materials for use in the electron injection layer include, but are not limited to, 8-quinolinolato lithium (Liq), LiF, Cs₂CO₃, Calcium (Ca), Barium (Ba), or a polyelectrolyte such as poly(ethylenimine) (PEI) or poly(ethylenimine) ethoxylated (PETE).

The EML 140 includes a compact multi-layer of QDs. The EML 140 is fabricated such that it is between the first CTL 130 and the second CTL 150. The EML 140 is a layer where holes and electrons are transported to combine and form excitons that decay while emitting a photon.

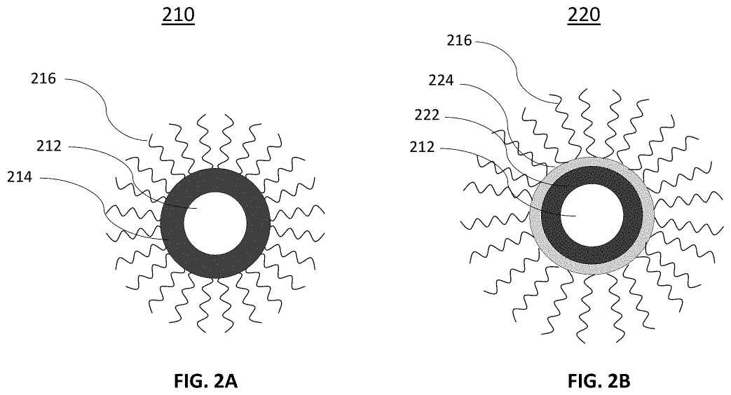

FIG. 2A illustrates a schematic diagram of a single shelled QD 210 and FIG. 2B illustrates a schematic diagram of a multiple shelled QD 220 according to the present disclosure.

As illustrated in FIG. 2A, the single shelled QD 210 includes a core 212 and shell 214 that include one or more of InP, CdSe, CdS, CdSeₓS₁₋ₓ, CdTe, CdₓZn₁₋ₓSe, CdₓZn₁₋ₓSe_{y}S_{1-y}, ZnSe, ZnS, ZnSTe, ZnSeTe, perovskites of the form ABX₃, Zn_{w}Cu_{z}In_{1-(w+z)}S, and carbon, where 0≤w, x, y, z≤1 and (w+z)≤1. The core 212 and shell 214 are surrounded by ligands 216.

The ligands 216 may passivate crystal defects in the core-shell QD 210 and provide improved solubility in some solvents as well as transport the charge from the CTLs to the EML. The ligands 216 may be long chain organic ligands, short chain organic ligands, inorganic molecular ligands and/or inorganic ion ligands.

The ligands 216 may be electron transporting and have electron conducting properties to improve the injection of electrons from the electron transport layer to a surface of the core-shell QDs.

Suitable materials for the electron transporting ligands 216 are alkyl, alkenyl, alkynyl or aryl (linear, branched or cyclic), carboxylic acids, and unsaturated and saturated acids, such as octainoic acids, dodecanoic acids, and oleic acids. Other embodiments of the electron transporting ligands 216 can include compounds such as phosphate, phosphinite or a thiolate group.

The electron transporting ligands 216 may be made of inorganic molecular materials such as metal-organic complexes. The electron transporting ligands 216 may be made of inorganic ion materials such as transition metals (e.g. Zn⁺).

The ligands 216 may be hole transporting and have hole conducting features to efficiently transport the positive charge carriers from the hole transport layer to the surface of the core-shell QDs.

Suitable materials for the hole transporting ligands 216 are alkyl, alicyclic, aromatic, tertiary, ethylene (linear or branched) amines with 1 to 20 atoms of carbon, mono-valent (or di- or tri-valent) alkyl, -alkenyl, -alkynyl or aryl (linear, branched or cyclic) phosphine or phosphine oxides with 1 to 60 atoms of carbon, and alkyl, -alkenyl, -alkynyl or aryl (linear, branched or cyclic) thiols with 1 to 30 atoms of carbon. The hole transporting ligands 216 may be made of inorganic molecular material such as metal-organic complexes. The hole transporting ligands 216 may be made of inorganic ion materials made of halides (e.g., I⁻, Br⁻ and Cl⁻), chalcogenides (e.g., S⁻, Se—, Te⁻), and thiocyanate (SCN⁻).

While the present disclosure is primarily directed to core-shell QDs 210 as illustrated in FIG. 2A the QDs may not be core-shell QDs 210, but rather core-multiple shell QDs 220 as illustrated in FIG. 2B. The core-multiple shell QDs 220 may be made from one or more previously described materials and not include the core-shell configuration. As illustrated in FIG. 2B, the core-multiple shells QDs 220 include a core 212, an inner shell 222 around the core, an outer shell 224 around the inner shell, and the ligands 216 around the outer shell. The inner shell 222 and outer shell 224 may be made from one or more of the previously described materials.

Multiple EML deposition processes are performed to achieve multi-layer EML. The first QD layer should be insoluble to the washing agent in order to prevent subsequent QD deposition washing away or intermixing with previously processed QD layers. To form such an insoluble QD layer, the QDs 210, 220 are processed in a matrix made of an insulating material such as a photoresist material, a dielectric material or an insulator material. This insulating material introduces several characteristic properties to the entire EML structure, specifically
help to form a QD layer with QDs uniformly distributed in each layer,
prevent excitons quenching both at the interface with QDs with different types of ligand within the EML and at the interfaces with the CTL (ETL, HTL) and the EML, and
act as an intrinsic region where most excitons are formed at the interface between adjacent QD layers.

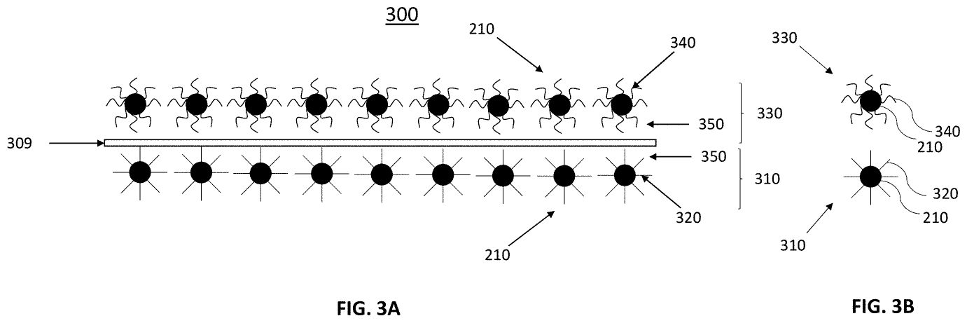

FIG. 3A and FIG. 3B illustrate a basic concept of the present disclosure. Two consecutive EMLs are deposited, specifically a first EML 310 having core-shell QDs 210 with hole transport ligands 320 and a second EML 330 having core-shell QDs 210 with electron transporting ligands 340. The core-shell QDs 210 may be made of material combinations as previously described.

As illustrated in FIGS. 3A and 3B, the first EML 310 includes a matrix of QDs 210 with ligands 320 that are hole transporting incorporated in an insulating (or dielectric) material 350 and the second EML 330 includes a matrix of QDs 210 with ligands 340 that are electron transporting and the insulating (or dielectric) material 350. The second EML 330 may only include the QDs 210 with electron transporting ligands 340.

Multiple EML deposition processes are performed to achieve multi-layer EML. The first QD 210 layer should be insoluble to the washing agent in order to prevent subsequent QD deposition washing away or intermixing with previously processed QD layers.

To form such an insoluble layer, the QDs 210, 220 are processed in a matrix made of an insulating material such as a photoresist material, a dielectric material or an insulating material. The insulating material introduces several characteristic properties to the entire EML structure, specifically to help to form a QD layer with QDs 210, 220 uniformly distributed in each layer, to prevent excitons quenching both at the interface 309 with QDs having different types of ligands within the EML and at the interfaces with the CTL (ETL, HTL) and the EML and to act as an intrinsic region where most excitons are formed at the interface between adjacent QD layers.

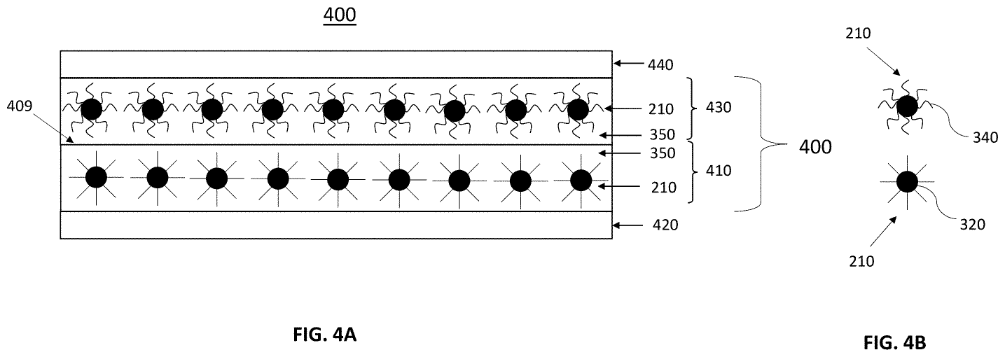

FIGS. 4A and 4B illustrate a multi-layer EML 400 between two CTLs of opposite polarity. As illustrated in FIG. 4A, a first EML 410 including a matrix incorporating QDs 210 with ligands 320 that are hole transporting with insulating (or dielectric) material 350 deposited on top of a hole transport layer (HTL) 420 and a second EML 430 including the insulating matrix incorporating QDs with ligands 340 that are electron transporting with the insulating (or dielectric) material deposited on top of the first EML. An electron transport layer (ETL) 440 is deposited on top of the second EML 430. The second EML 430 may include only QDs 210 with electron transporting ligands 340.

Referring back to FIG. 3A, the first EML 310 may include a matrix incorporating the QDs 210 with the ligands 320 which are electron transporting and the insulating (or dielectric) materials 350. In such an implementation, the first EML 310 is deposited on top of an electron transport layer. The second EML 330 may include a matrix including the QDs 210 with the ligands 340 which is hole transporting and the insulating (or dielectric) material 350 is deposited on top of the first EML 310. A hole transport layer is subsequently deposited on top of the second EML 330. In some implementations of the present disclosure, the second EML 330 may include only the QDs 210 with the hole transporting ligands 340.

Some implementations of the present disclosure may include a plurality of the EMLs as previously described for each type of QDs 210, 220 used.

A method of making an LED including the previously disclosed multi-layer EML is with regard to FIGS. 4A and 4B.

Referring to FIG. 4A, the QDs 210 with the hole transporting ligands 320 are mixed in a solution with photo-responsive, dielectric or insulating materials 350 such as photo-initiator, PMMA, PFO, or polymide precursor in a compatible solvent. The solvent is selected such that the QDs 210 with the hole transporting ligands 320 and insulating materials 350 are soluble but do not dissolve previously deposited CTLs.

Suitable solvents include but are not limited to acetone, dichloromethane, chloroform, ethyl acetate, linear or branched alkanes (such as pentane, hexane, heptane, octane, nonane, decane, undecane, and dodecane), linear or branched alcohols (such as butanol, 2-propanol, propanol, ethanol, and methanol), linear or branched alkoxy alcohols (such as 2-Methoxyethanol, 2-Ethoxyethanol), mono, di and tri halogen substituted benzenes (such as chlorobenzene, 1,2-dibromobenzene, 1,3-dibromobenzene, 1,4-dibromobenzene, 1,3,5-tribromobenzene, and 1,2,4-tribromobenzene), and linear or branched ethers, and/or mono, di and tri alkyl substituted benzenes (such as toluene, 1,2-Dimethylbenzene, 1,3-Dimethylbenzene, and 1,4-Dimethylbenzene). The particular solvent utilized may depend on the hole transporting ligands 320 and the insulating material 350 that are selected. The total concentration of the solution may range from 0.1 to 20% wt.

The first EML 410 is deposited on top of the HTL 420 from the solution of the QDs 210 with the hole transporting ligands 320 and the insulating material 350 by solution processing such as spin coating, doctor blading, dip coating, printing, and spray coating.

A curing process or/and lithography process may be carried out to facilitate evaporation/removal of the solvent. The technique selected depends on the photo-responsive, dielectric or insulating materials used in the matrix.

An annealing process may be performed at any suitable temperature that effectuates evaporation of the solvent while also maintaining integrity of the QDs 210 structure and the underlying HTL 420. The annealing may be performed at a temperature ranging from 5° C. to 150° C. or ranging from room temperature (18° C., also known as slow dry) to 80° C.

A photolithography process may be performed and a photo-resist, time exposure time and intensity to light-exposure (such X-ray, UV, Visible, NIR and IR range) may be selected so that the first EML 410 and the HTL 420 are not damaged. Any additional steps, such as passivation or surface modification, to improve the surface should be selected to not alter the integrity of the underlying CTL and the EML layer.

The QDs 210 with the electron transporting ligands 340 are mixed in solution with the photo-responsive, dielectric or insulating materials 350 such as photo-initiator, PMMA, PFO, and polymide precursor in compatible solvent(s). The QDs 210 with the hole transporting ligands 320 may be dissolved in a solvent without any additional materials. The solvent is selected such that the QDs 210 and the insulating materials 350 are soluble but do not dissolve previously deposited emitting layers or damage/disrupt the interface 409 with the previous emitting layers.

The second EML 430 is deposited by solution processing such as spin coating, doctor blading, dip coating, printing, and spray coating on top of the first EML 410 from a solution including either the insulating material 350 and material for the ETL 440, or only the material for the ETL. The second EML 430 may be formed by incorporating the QDs 210 with the electron transporting ligands 340 in a matrix of the photo-responsive, dielectric or insulating materials 350.

The QDs 210 with the electron transporting ligands 340 may be directly deposited on top of the first EML 410. However, using matrix material is desirable, but not crucial, to prevent exciton quenching at the interface 409 between the second EML 430 and the ETL 440.

The photolithography and the curing processes may be combined when the QDs 210 are incorporated in a matrix. The curing processes may be carried out if the EML 430 including QDs 210 is not incorporated in a matrix. The curing processes may facilitate evaporation/removal of the solvent(s).

The annealing process may be performed at any suitable temperature that effectuates evaporation of the solvent while also maintaining the integrity of the QDs 210, the underlying EML 410 and CTL material. The annealing process may be performed at a temperature ranging from 5° C. to 150° C. or ranging from room temperature (18° C., also known as slow dry) to 80° C.

The photolithography process may be carried out when the QDs 210 are in an insulating matrix. The photoresist, exposure time and intensity to light-exposure such as X-ray, UV, Visible, NIR and IR range in the photolithography process may be selected to not damage the underlying EMLs and the CTLs.

An inverted structure may be utilized in which the ETL 440 is deposited on a substrate of an LED. Other embodiments may utilize the single EMLs 430 with multi-layer QDs 210 with similar and compatible ligands.

In the inverted structure, the first EML 410 is an insulating (or dielectric) matrix incorporating the QDs 210 with electron transporting ligands 340 and the second EML 430 is either an insulating (or dielectric) matrix incorporating the QDs with hole transporting ligands 320 or a layer of the QDs with the hole transporting ligands. The HTL 420 is then deposited on top of the last QD 210 layer of the EML 430.

From the previous description, it is clear that various techniques may be used for implementing the concepts described in the present disclosure without departing from the scope of those concepts. While the disclosure is with regard to specific implementations, a person of ordinary skill in the art will recognize that changes may be made in form and detail without departing from the scope of the disclosure.

Therefore, the disclosed implementations are to be considered in all respects as illustrative and not restrictive. It should also be understood that the present disclosure is not limited to the particular implementations described since many rearrangements, modifications, and substitutions are possible without departing from the scope of the present disclosure.

What is claimed is:

1. A light emitting device comprising:
a first electrode;
a second electrode; and
an emissive layer between the first and the second electrodes, the emissive layer comprising:
a first plurality of quantum dots having hole transporting ligands; and
a second plurality of quantum dots having electron transporting ligands,
wherein at least one of the first plurality of quantum dots and the second plurality of quantum dots is incorporated in a matrix.

2. The light emitting device of claim 1, wherein the first plurality of quantum dots is disposed in a first layer of the emissive layer, and the second plurality of quantum dots is disposed in a second layer of the emissive layer.

3. The light emitting device of claim 1, wherein the matrix comprises at least one of an electrically insulating material, a photo-responsive material, and a dielectric material.

4. The light emitting device of claim 1, wherein the matrix comprises cross-linked molecules, the cross-linked molecules transport charge carriers to or away from the at least one of the first plurality of quantum dots and the second plurality of quantum dots that is incorporated in the matrix.

5. The light emitting device of claim 1, wherein the matrix isolates and confines the at least one of the first plurality of quantum dots and the second plurality of quantum dots at an interface between the matrix and the at least one of the first plurality of quantum dots and the second plurality of quantum dots that is incorporated in the matrix.

6. The light emitting device of claim 1, further comprising a hole transporting layer between the emissive layer and the first electrode, the first electrode being an anode electrode.

7. The light emitting device of claim 6, further comprising a hole injecting layer between the hole transporting layer and the anode electrode.

8. The light emitting device of claim 1, further comprising an electron transporting layer between the emissive layer and the second electrode, the second electrode being a cathode electrode.

9. The light emitting device of claim 8, further comprising an electron injecting layer between the electron transporting layer and the cathode electrode.

10. The light emitting device of claim 1, wherein at least one quantum dot in the first and the second pluralities of quantum dots comprises a core and at least one shell enclosing the core.

11. The light emitting device of claim 1, further comprising:
a substrate,
wherein the first electrode is an anode disposed on one side of the emissive layer facing the substrate; and
wherein the second electrode is a cathode disposed on another side of the emissive layer facing away from the substrate.

12. The light emitting device of claim 11, further comprising:
a hole transporting layer between the first electrode and the emissive layer; and
an electron transporting layer between the emissive layer and the second electrode.

13. The light emitting device of claim 1, further comprising:
a substrate,
wherein the first electrode is a cathode disposed on one side of the emissive layer facing the substrate; and
wherein the second electrode is an anode disposed on another side of the emissive layer facing away from the substrate.

14. The light emitting device of claim 13, further comprising:
an electron transporting layer between the first electrode and the emissive layer; and
a hole transporting layer between the emissive layer and the second electrode.

15. An emissive layer of a light emitting device, the emissive layer comprising:
a first plurality of quantum dots having hole transporting ligands; and
a second plurality of quantum dots having electron transporting ligands,
wherein at least one of the first plurality of quantum dots and the second plurality of quantum dots is incorporated in a matrix.

16. The emissive layer of claim 15, wherein the matrix comprises at least one of an electrically insulating material, a photo-responsive material, and a dielectric material.

17. The emissive layer of claim 15, wherein the matrix comprises cross-linked molecules, the cross-linked molecules transport charge carriers to or away from the at least one of the first plurality of quantum dots and the second plurality of quantum dots that is incorporated in the matrix.

18. The emissive layer of claim 15, wherein the matrix isolates and confines the at least one of the first plurality of quantum dots and the second plurality of quantum dots at an interface between the matrix and the at least one of the first plurality of quantum dots and the second plurality of quantum dots that is incorporated in the matrix.

19. The emissive layer of claim 15, wherein at least one quantum dot in the first and the second pluralities of quantum dots comprises a core and at least one shell enclosing the core.
